(19) United States
(12) Patent Application Publication
(10) Pub. No.: US 2026/0254184 A1
(43) Pub. Date: Aug. 27, 2026

(54) STRUCTURE COMPRISING CABLE AND BOARD AND FABRICATION METHOD THEREOF

(71) Applicant: JAPAN AVIATION ELECTRONICS INDUSTRY, LIMITED, Tokyo (JP)

(72) Inventors: Gota KAMEYAMA, Tokyo (JP); Yukitaka TANAKA, Tokyo (JP); Kentaro TODA, Tokyo (JP); Takahiro YAMAGUCHI, Tokyo (JP); Kousei KURISHIMA, Tokyo (JP)

(73) Assignee: JAPAN AVIATION ELECTRONICS INDUSTRY, LIMITED, Tokyo (JP)

(21) Appl. No.: 19/437,360

(22) Filed: Dec. 31, 2025

(30) Foreign Application Priority Data
Feb. 27, 2025 (JP) 2025-030620

(51) Int. Cl. H01R 43/02; H01R 12/53

(52) U.S. Cl. CPC H01R 43/02; H01R 12/53

(57) ABSTRACT

A structure comprises a cable and a board. The cable comprises at least one core wire, an insulation portion covering the core wire and a shield portion covering the insulation portion. The board is formed with a ground pad. The shield portion is soldered to the ground pad. The ground pad has a predetermined length in a direction in which the shield portion extends. The cable is configured so that its characteristic impedance is kept to a predetermined constant value. The cable has a predetermined section which includes the shield portion and extends from an end of the shield portion to a position apart from the end of the shield portion by three times the predetermined length. A difference between a maximum value of the characteristic impedance in the predetermined section and the predetermined constant value is equal to or less than 5 Ω.

### CROSS REFERENCE TO RELATED APPLICATIONS

This application is based on and claims priority under 35 U.S.C. §119 to Japanese Patent Application No. JP 2025-030620 filed February 27, 2025, the content of which is incorporated herein in its entirety by reference.

### BACKGROUND OF THE INVENTION

This invention relates to a structure comprising a cable and a board.

For example, this type of structure is disclosed in JP2018-137239A (Patent Document 1), the content of which is incorporated herein by reference.

Referring to FIG. 7, Patent Document 1 discloses a structure 90 comprising a cable 92 and a board 98. The cable 92 comprises a core wire 93, an insulation portion 94 covering the core wire 93, a shield portion 95 covering the insulation portion 94 and a sheath 96 covering the shield portion 95. The board 98 is formed with various conductive pads 99. The core wire 93 and the shield portion 95 are exposed outward from the sheath 96 and are fixed on and connected to the conductive pads 99, respectively.

The shield portion of an existing structure such as the structure 90 of Patent Document 1 is usually connected to a conductive pad via pulse-heating. In detail, a heater chip presses the shield portion against the conductive pad which is applied with solder while the solder is heated by the heater chip. The thus-pressed shield portion is soldered to the conductive pad. This existing connection method via pulse-heating tends to change characteristic impedance of a part of the shield portion which is pressed and heated by the heater chip and characteristic impedance therearound. As a result, signal transmission characteristics of the cable might be degraded. Accordingly, there is a growing demand to reduce change in characteristic impedance as signal frequency becomes higher.

### SUMMARY OF THE INVENTION

It is therefore an object of the present invention to provide a structure which can reduce change in characteristic impedance.

An aspect of the present invention provides a fabrication method of a structure comprising a cable and a board. The fabrication method comprises a preparing step, an arranging step and a soldering step. In the preparing step, the cable and the board are prepared. The cable comprises at least one core wire, an insulation portion covering the core wire and a shield portion covering the insulation portion. The board is formed with a ground pad applied with solder. In the arranging step, the shield portion of the cable is arranged on the solder of the board. In the soldering step, the shield portion is soldered to the ground pad by heating the shield portion and the solder in a contactless manner via electromagnetic induction and thereby melting the solder.

Another aspect of the present invention provides a structure comprising a cable and a board. The cable comprises at least one core wire, an insulation portion covering the core wire and a shield portion covering the insulation portion. The board is formed with a ground pad. The shield portion is soldered to the ground pad. The ground pad has a predetermined length in a direction in which the shield portion extends. The cable is configured so that its characteristic impedance is kept to a predetermined constant value. The cable has a predetermined section which includes the shield portion and extends from an end of the shield portion to a position apart from the end of the shield portion by three times the predetermined length. A difference between a maximum value of the characteristic impedance in the predetermined section and the predetermined constant value is equal to or less than 5 Ω.

In general, characteristic impedance of a cable largely affects signal transmission characteristics of the cable. Accordingly, the cable is preferred to have characteristic impedance which is kept to a designed predetermined constant value regardless of the position of the cable. However, during a typical soldering step in which a shield portion of a cable is soldered to a ground pad of a board, characteristic impedance of the cable tends to be changed from the predetermined constant value at a part of the shield portion soldered to the ground pad and therearound because of heat and pressure applied thereto. In contrast, according to the cable of an aspect of the present invention, change in characteristic impedance which might be caused because of pressure applied upon soldering is prevented. More specifically, change in characteristic impedance is equal to or less than 5 Ω even at a part of the shield portion soldered to the ground pad and therearound. Thus, an aspect of the present invention provides a structure which can reduce change in characteristic impedance.

Moreover, according to the fabrication method of an aspect of the present invention, the shield portion can be soldered to the ground pad with no pressure applied thereto via induction heating (IH) reflow, for example. This soldering step can reduce change in characteristic impedance of the cable to 5 Ω or less even at a part of the shield portion soldered to the ground pad and therearound. Thus, an aspect of the present invention provides a fabrication method suitable for fabricating the structure of an aspect of the present invention.

An appreciation of the objectives of the present invention and a more complete understanding of its configuration may be had by studying the following description of the preferred embodiment and by referring to the accompanying drawings.

### BRIEF DESCRIPTION OF THE DRAWINGS

FIG. 1 is a perspective view schematically showing a structure according to an embodiment of the present invention, wherein a hidden outline of a shield portion of a cable of the structure is illustrated with dashed line.

FIG. 2 is a view showing steps for fabricating the structure of FIG. 1.

FIG. 3 is a side view schematically showing the structure under a soldering step of FIG. 2.

FIG. 4 is a side view showing the cable which is bent during a preparing step of FIG. 2.

FIG. 5 is a side view showing a first modification of the structure of FIG. 3, wherein a hidden outline of the cable is illustrated with dashed line.

FIG. 6 is a side view showing a second modification of the structure of FIG. 3, wherein a hidden outline of the cable is illustrated with dashed line.

FIG. 7 is a cross-sectional view showing a structure of Patent Document 1.

While the invention is susceptible to various modifications and alternative forms, specific embodiments thereof are shown by way of example in the drawings and will herein be described in detail. It should be understood, however, that the drawings and detailed description thereto are not intended to limit the invention to the particular form disclosed, but on the contrary, the intention is to cover all modifications, equivalents and alternatives falling within the spirit and scope of the present invention as defined by the appended claims.

### DETAILED DESCRIPTION

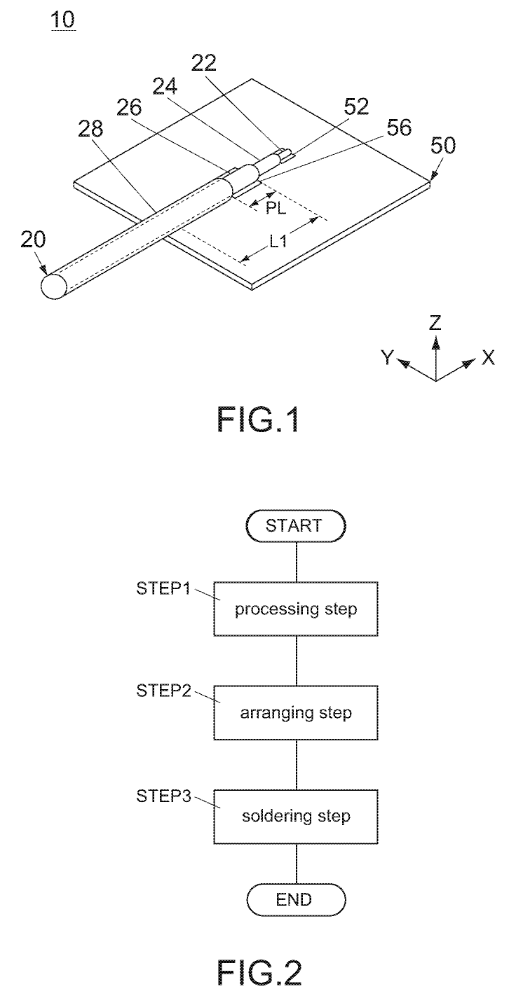

As shown in FIG. 1, a structure 10 according to an embodiment of the present invention comprises a cable 20 and a board 50. The board 50 of the present embodiment is a circuit board incorporated in an electronic device (not shown). The illustrated end of the cable 20 of the present embodiment is electrically connected with the electronic device via the board 50. The cable 20 has another end which is connected to a mate electronic device (not shown). The cable 20 transmits high-frequency signals between the electronic device and the mate electronic device through the board 50. The structure 10 of the present embodiment works as described above. However, the present invention is not limited thereto but is applicable to various structures. For example, the structure 10 may comprise two or more of the cables 20 arranged in a lateral direction (Y-direction).

The cable 20 of the present embodiment extends along a front-rear direction perpendicular to the lateral direction and is connected to an upper surface of the board 50 in an up-down direction perpendicular to both the lateral direction and the front-rear direction. The front-rear direction of the present embodiment is the X-direction. In the present embodiment, “forward” means the positive X-direction, and “rearward” means the negative X-direction. The up-down direction of the present embodiment is the Z-direction. In the present embodiment, “upward” means the positive Z-direction, and “downward” means the negative Z-direction. The words such as the lateral direction, the front-rear direction and the up-down direction do not indicate the absolute positional relation relative to the ground but merely indicate a relative positional relation under a definition that the direction along which the illustrated cable 20 extends is the front-rear direction.

The cable 20 of the present embodiment is a typical coaxial cable. In detail, the cable 20 is a micro-coaxial cable. The cable 20 comprises one core wire 22 made of conductor, an insulation portion 24 made of insulator and covering the core wire 22 in a vertical plane (YZ-plane) perpendicular to the front-rear direction, a shield portion 26 made of conductor and covering the insulation portion 24 in the vertical plane and a sheath 28 made of insulator and covering the shield portion 26 in the vertical plane. However, the present invention is not limited thereto. The configuration of the cable 20 is not specifically limited, provided that the cable 20 comprises the core wire 22, the shield portion 26 and the insulation portion 24 which insulates the core wire 22 and the shield portion 26 from each other.

For example, the number of the core wire 22 may be two or more. More specifically, the cable 20 may be a twisted pair cable or a parallel pair cable. Thus, the cable 20 may comprise at least one of the core wires 22, the insulation portion 24 covering the core wire 22 and the shield portion 26 covering the insulation portion 24. The shield portion 26 may be formed of metal foil or may be a braid formed of fine metal wires.

The core wire 22 of the present embodiment is a part for transmitting high-frequency signals. The shield portion 26 of the present embodiment is a part for protecting the core wire 22 from electromagnetic interference. The cable 20 has characteristic impedance when the core wire 22 transmits high-frequency signals. In general, characteristic impedance varies dependent on the part of the cable 20. Moreover, characteristic impedance of the cable 20 largely affects transmission characteristics of high-frequency signals. Accordingly, characteristic impedance of a general cable is defined by a standard. The cable 20 is configured similarly to a general cable so that its characteristic impedance is kept to a predetermined constant value. The predetermined constant value of the cable 20 is 90 Ω, for example.

The board 50 of the present embodiment has a rectangular flat-plate shape perpendicular to the up-down direction. The board 50 is formed with various conductive patterns. For example, the board 50 is formed with a signal pad 52 and a ground pad 56. The signal pad 52 is connected to the electronic device (not shown) via a conductive line (not shown). The ground pad 56 is grounded to a ground pattern (not shown). The board 50 of the present embodiment has the aforementioned configuration. However, the present invention is not limited thereto. The configuration of the board 50 can be modified as necessary. For example, the board 50 may be formed with two or more of the signal pads 52 which correspond to two or more of the cables 20, respectively.

The core wire 22 of the cable 20 of the present embodiment is soldered to the signal pad 52 of the board 50. The shield portion 26 of the cable 20 of the present embodiment is soldered to the ground pad 56 of the board 50. The ground pad 56 has a predetermined length PL in the front-rear direction in which the shield portion 26 extends. The cable 20 has a predetermined section which includes the shield portion 26 and extends from an end (front end) of the shield portion 26 to a position apart from the end of the shield portion 26 by a length L1, which is three times the predetermined length PL. A difference between a maximum value of the characteristic impedance in the predetermined section and the predetermined constant value is equal to or less than 5 Ω.

The cable 20 is preferred to have characteristic impedance which is kept to the designed predetermined constant value regardless of the position of the cable 20. Accordingly, the core wire 22 is located at the center of the cable 20 in the vertical plane (YZ-plane), and the shield portion 26 is arranged in a circular shape about the core wire 22 in the vertical plane. However, according to the existing technique, during a typical soldering step in which the shield portion 26 of the cable 20 is soldered to the ground pad 56 of the board 50, a positional relation between the core wire 22 and the shield portion 26 in the vertical plane might be easily changed at a part of the shield portion 26 soldered to the ground pad 56 and therearound because of heat and pressure applied thereto. As a result, characteristic impedance tends to be largely changed from the predetermined constant value.

In contrast, as described below, the present embodiment prevents change in characteristic impedance which might be caused by the pressure applied upon soldering, and thereby change in characteristic impedance is equal to or less than 5 Ω even at a part of the shield portion 26 soldered to the ground pad 56 and therearound. Thus, the present embodiment provides the structure 10 which can reduce change in characteristic impedance.

Hereafter, explanation will be made about a fabrication method according to the present embodiment, or the fabrication method of the structure 10 comprising the cable 20 and the board 50.

Referring to FIG. 2 together with FIG. 1, the structure 10 of the present embodiment is fabricated via three steps consisting of a preparing step (step 1), an arranging step (step 2) and a soldering step (step 3). However, the fabrication method shown in FIG. 2 and the fabrication method described below are merely examples and can be modified as necessary.

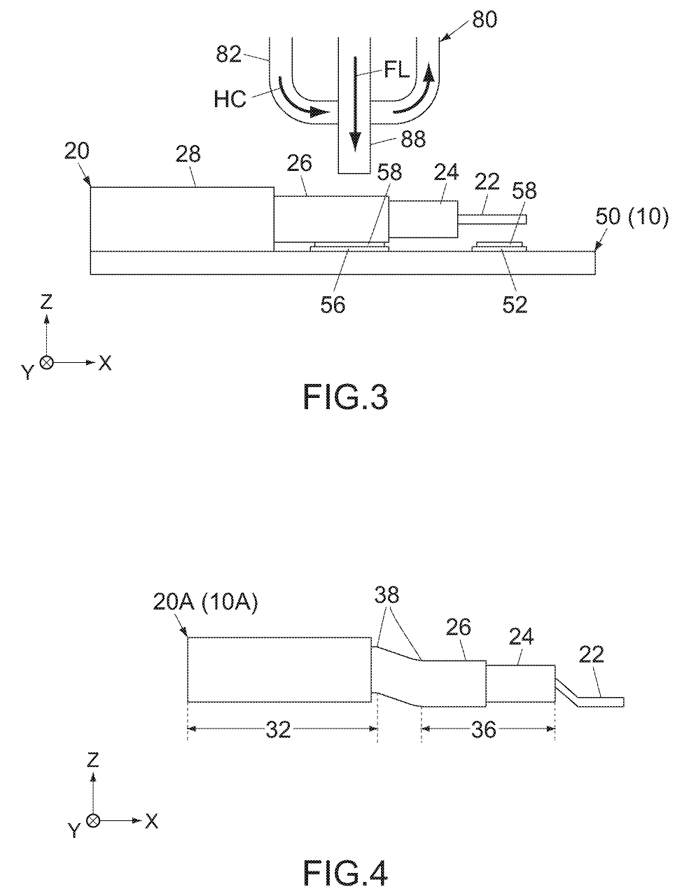

Referring to FIG. 2 together with FIG. 3, in the preparing step, firstly, the cable 20 and the board 50 are prepared. Then, the sheath 28, the shield portion 26 and the insulation portion 24 of a front end part of the cable 20 are sequentially removed, so that the core wire 22, the insulation portion 24 and the shield portion 26 are exposed outward of the cable 20 as shown in FIG. 3. Moreover, each of the signal pad 52 and the ground pad 56 of the board 50 is applied with solder 58.

Summarizing the explanation described above, the fabrication method of the present embodiment comprises preparing the cable 20 and the board 50, the cable 20 comprising the at least one core wire 22, the insulation portion 24 covering the core wire 22 and the shield portion 26 covering the insulation portion 24, the board 50 being formed with the ground pad 56 applied with the solder 58.

Then, in the arranging step, the cable 20 is arranged on the board 50. In detail, the sheath 28 is placed on the upper surface of the board 50 so that the core wire 22 is located just over the signal pad 52 applied with the solder 58, and the shield portion 26 is located just over the ground pad 56 applied with the solder 58. The solder 58 of the ground pad 56 of the thus-arranged cable 20 is preferred to be sufficiently in contact with the shield portion 26 which is arranged as described above.

Summarizing the explanation described above, the fabrication method of the present embodiment comprises arranging the shield portion 26 of the cable 20 on the solder 58 of the board 50.

Then, in the soldering step, the core wire 22 and the shield portion 26 are soldered to the signal pad 52 and the ground pad 56, respectively.

Referring to FIG. 3, according to the present embodiment, the shield portion 26 is soldered with no pressure applied thereto via induction heating (IH) reflow in which a soldering device 80 is used. The soldering device 80 illustrated in FIG. 3 is a schematic illustration of an actual device and comprises a coil 82 and a magnetic flux concentrator 88. The coil 82 is connected to an AC power source (not shown) and is wound around the magnetic flux concentrator 88. When a high frequency current HC flows through the coil 82, the magnetic flux concentrator 88 generates magnetic flux FL. The magnetic flux FL generates eddy currents in conductive parts such as the shield portion 26 and the solder 58 located in the vicinity of the magnetic flux concentrator 88, and thereby the shield portion 26 and the solder 58 generate heat. As a result, the solder 58 is melted, and the shield portion 26 is soldered to the ground pad 56.

In contrast, according to the existing technique, the shield portion 26 is soldered via pulse-heating. In detail, the shield portion 26 is pressed against the ground pad 56 applied with the solder 58 by a heater chip (not shown) while the solder 58 is heated and melted by the heater chip, and thereby the shield portion 26 is soldered to the ground pad 56. According to the existing connection via pulse-heating, the shield portion 26 tends to be deformed by pressure. In addition, the insulation portion 24 tends to be partially melted to be deformed by heat applied from the heater chip. As a result, the positional relation between the core wire 22 and the shield portion 26 in the vertical plane (YZ-plane) may be largely changed, and thereby characteristic impedance tends to be changed at a part of the shield portion 26 pressed and heated by the heater chip and therearound. The present embodiment can prevent change in characteristic impedance which might be caused by the existing technique.

Summarizing the explanation described above, the fabrication method of the present embodiment comprises soldering the shield portion 26 to the ground pad 56 by heating the shield portion 26 and the solder 58 in a contactless manner via electromagnetic induction and thereby melting the solder 58.

The soldering method of the present embodiment can prevent deformation of the shield portion 26 which might be caused by pressure. In addition, deformation of the insulation portion 24 can be reduced because the electromagnetic induction generates no heat in the insulation portion 24. Accordingly, the positional relation between the core wire 22 and the shield portion 26 in the vertical plane (YZ-plane) can be substantially kept to the positional relation before the soldering step (see FIG. 2). More specifically, the shield portion 26 is substantially arranged in a circular shape about the core wire 22 in the vertical plane even after the soldering step. As a result, change in characteristic impedance can be reduced to 5 Ω or less at the shield portion 26 and therearound. Thus, the present embodiment provides the fabrication method suitable for fabricating the structure 10 of the present embodiment.

The core wire 22 of the cable 20 may be soldered to the signal pad 52 via pulse-heating after the shield portion 26 is soldered. More specifically, the core wire 22 may be pressed against the solder 58 of the signal pad 52 while the solder 58 is heated to be melted. The core wire 22 may be also soldered via the IH reflow without being pressed. For example, in an instance in which each of the insulation portion 24 and the shield portion 26 is thin, the solder 58 may be thickly applied on the signal pad 52 so that the solder 58 is in contact with the core wire 22 arranged thereon. The core wire 22 and the shield portion 26 under this condition may be simultaneously soldered via IH reflow.

According to the present embodiment, the shield portion 26 and the solder 58 are heated in a contactless manner via the aforementioned IH reflow. However, the present invention is not limited thereto. The heating method is not specifically limited, provided that the shield portion 26 and the solder 58 can be heated in a contactless manner via electromagnetic induction. Moreover, the configuration of the soldering device 80 is not specifically limited. The soldering device 80 may be configured so that the shield portions 26 of two or more of the cables 20 can be simultaneously soldered.

The fabrication method described above is particularly suitable for a micro-coaxial cable. However, the fabrication method described above is not limited to the cable 20 which is a coaxial cable but can be applicable to various cables.

Hereafter, explanation will be made about modifications of the fabrication method of the present embodiment.

Referring to FIG. 4 together with FIG. 3, when the cable 20 is arranged on the board 50 so as to extend straight along the front-rear direction, the shield portion 26 might be largely apart from the ground pad 56 depending on the thickness of the sheath 28 of the cable 20. The thus-located shield portion 26 sometimes cannot be brought into contact with the solder 58 even if the solder 58 is thickly applied on the ground pad 56. In such an instance, the cable 20 should be bent during a bending process before being arranged on the board 50. Thus, a cable 20A which is bent during a bending process may be used instead of the cable 20.

Referring to FIG. 4, the cable 20A may be bent at two bent portions 38. This bending process forms a first portion 32 and a second portion 36 of the cable 20A. The first portion 32 mainly includes the sheath 28. The second portion 36 includes the shield portion 26 exposed outward from the sheath 28. Each of the first portion 32 and the second portion 36 extends along the front-rear direction. The first portion 32 and the second portion 36 which are formed as described above extend in parallel to each other within the range of tolerance. This bending process does not substantially affect the positional relation between the core wire 22 and the shield portion 26 in the vertical plane (YZ-plane).

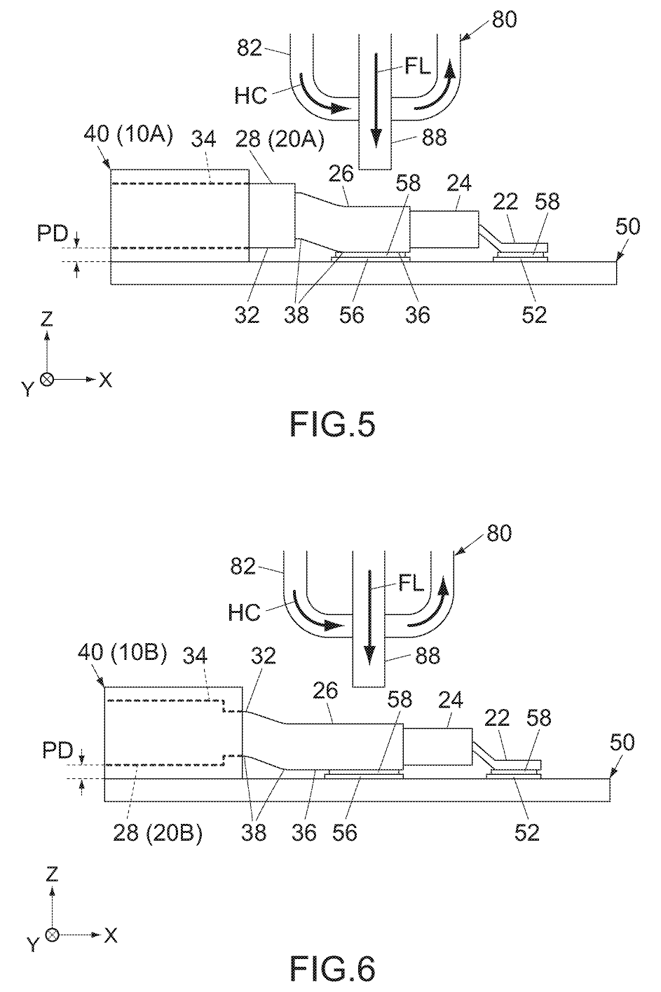

According to the present modification, the lower end of the shield portion 26 of the second portion 36 is located below the lower end of the sheath 28 of the first portion 32. The core wire 22 of the cable 20A is also bent. The lower end of the thus-bent core wire 22 is located further below the lower end of the shield portion 26 of the second portion 36 and extends along the front-rear direction. However, the present invention is not limited thereto. For example, the core wire 22 may be bent as necessary. The position of the lower end of the shield portion 26 of the second portion 36 may be properly designed so that the shield portion 26 is brought into contact with the solder 58 when the cable 20A is arranged on the board 50 (see FIG. 5).

The cable 20A illustrated in FIG. 4 has the configuration same as that of the cable 20 (see FIG. 3) except that the cable 20A is bent during a bending process. However, the present invention is not limited thereto. For example, the sheath 28 of the cable 20A may be rather thicker than the sheath 28 (see FIG. 3) of the cable 20.

Summarizing the explanation described above, in the preparing (see FIG. 2) according to the present modification, the cable 20A is bent so that the cable 20A is formed with the first portion 32 and the second portion 36 extending in parallel to each other.

Referring to FIG. 5, the cable 20A may be arranged on the upper surface of the board 50 using a holding member 40. For example, the holding member 40 may be a locator fixed on the upper surface of the board 50. In this instance, the cable 20A has a held portion 34. The held portion 34 is a part of the first portion 32 of the cable 20A. The cable 20A can be easily arranged at a designed predetermined position by holding the held portion 34 using the holding member 40. More specifically, the first portion 32 can be arranged at a position which is apart from the upper surface of the board 50 by a predetermined distance PD. The second portion 36 of the thus-arranged cable 20A can be arranged on the board 50 so that the shield portion 26 is brought into contact with the solder 58 of the ground pad 56.

Summarizing the explanation described above, in the arranging (see FIG. 2) of the present modification, the held portion 34, which is a part of the first portion 32, is held by the holding member 40, and thereby the second portion 36 is arranged on the board 50 while the first portion 32 is arranged to be apart from the board 50 by the predetermined distance PD.

The aforementioned fabrication method according to the modification fabricates a structure 10A according to a first modification. The structure 10A comprises the cable 20A, the holding member 40 and the board 50. The cable 20A has the held portion 34 and the bent portions 38. The cable 20A is bent at each of the bent portions 38. The held portion 34 is held by the holding member 40. The held portion 34 and the board 50 are apart from each other by the predetermined distance PD. The bent portions 38 are located between the held portion 34 and a part of the shield portion 26 which is soldered to the ground pad 56.

The predetermined distance PD of the present modification is preferred to be 0.35 mm or less. The micro-coaxial cable is hard and is difficult to bend. The bending amount of the micro-coaxial cable can be reduced by reducing the size of the holding member 40 so that the predetermined distance PD becomes a small size equal to or less than 0.35 mm. However, the present invention is not limited thereto. For example, the predetermined distance PD may be designed in accordance with the function of the holding member 40.

The present embodiment can be further variously modified in addition to the already described various modifications.

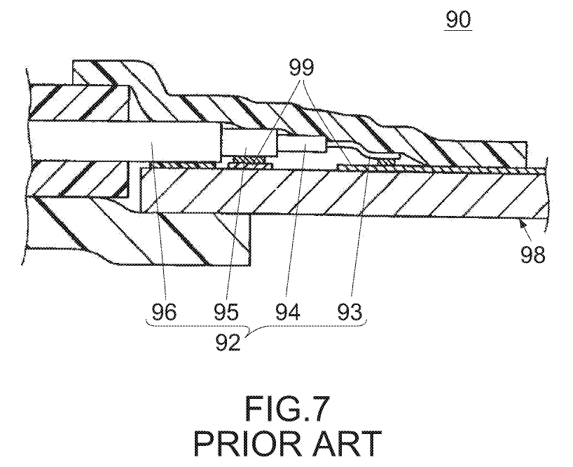

For example, referring to FIG. 6, a structure 10B according to a second modification comprises a cable 20B, the holding member 40 and the board 50. Comparing FIG. 6 with FIG. 5, the held portion 34 of the cable 20B is different from the held portion 34 of the cable 20A. More specifically, the held portion 34 of the cable 20B includes a rear end of the shield portion 26. The structure 10B has a configuration similar to that of the structure 10A except for this difference and can be fabricated by a fabrication method similar to that of structure 10A.

While there has been described what is believed to be the preferred embodiment of the invention, those skilled in the art will recognize that other and further modifications may be made thereto without departing from the spirit of the invention, and it is intended to claim all such embodiments that fall within the true scope of the invention.

What is claimed is:

1. A fabrication method of a structure comprising a cable and a board, the fabrication method comprising:
preparing the cable and the board, the cable comprising at least one core wire, an insulation portion covering the core wire and a shield portion covering the insulation portion, the board being formed with a ground pad applied with solder;
arranging the shield portion of the cable on the solder of the board; and
soldering the shield portion to the ground pad by heating the shield portion and the solder in a contactless manner via electromagnetic induction and thereby melting the solder.

2. The fabrication method as recited in claim 1, wherein:
in the preparing, the cable is bent so that the cable is formed with a first portion and a second portion extending in parallel to each other; and
in the arranging, a held portion, which is a part of the first portion, is held by a holding member, and thereby the second portion is arranged on the board while the first portion is arranged to be apart from the board by a predetermined distance.

3. The fabrication method as recited in claim 2, wherein the predetermined distance is 0.35 mm or less.

4. A structure comprising a cable and a board, wherein:
the cable comprises at least one core wire, an insulation portion covering the core wire and a shield portion covering the insulation portion;
the board is formed with a ground pad;
the shield portion is soldered to the ground pad;
the ground pad has a predetermined length in a direction in which the shield portion extends;
the cable is configured so that its characteristic impedance is kept to a predetermined constant value;
the cable has a predetermined section which includes the shield portion and extends from an end of the shield portion to a position apart from the end of the shield portion by three times the predetermined length; and
a difference between a maximum value of the characteristic impedance in the predetermined section and the predetermined constant value is equal to or less than 5 Ω.

5. The structure as recited in claim 4, wherein:
the structure comprises a holding member;
the cable has a held portion and a bent portion;
the cable is bent at the bent portion;
the held portion is held by the holding member;
the held portion and the board are apart from each other by a predetermined distance; and
the bent portion is located between the held portion and a part of the shield portion which is soldered to the ground pad.

6. The structure as recited in claim 5, wherein the predetermined distance is 0.35 mm or less.
